(19) United States
(12) Patent Application Publication
(10) Pub. No.: US 2015/0244149 A1
(43) Pub. Date: Aug. 27, 2015

(54) Tunable Semiconductor Device And Method For Making Tunable Semiconductor Device

(71) Applicant: EUPhoenix B.V., Breda (NL)

(72) Inventor: Bob Van Someren, Rotterdam (NL)

(73) Assignee: EUPhoenix B.V., Breda (NL)

(21) Appl. No.: 14/403,989

(22) PCT Filed: May 30, 2012
(86) PCT No.: PCT/EP2012/060173

§ 371 Date: Nov. 25, 2014

(51) Int. Cl. H01S 5/12; H01S 5/20; H01S 5/343; H01S 5/22

(52) U.S. Cl. CPC H01S 5/1234; H01S 5/22; H01S 5/2031; H01S 5/343

(57) ABSTRACT

Method and apparatus for a tunable laser device. In one aspect, a tunable laser device comprises a first doped cladding layer on a semiconductor substrate, a first waveguide layer of essentially undoped piezoelectric material on a top surface of the first doped cladding layer, an active layer on the top surface of the first waveguide layer, a second waveguide layer of essentially undoped piezoelectric material on the top surface of the active layer, a longitudinal structure parallel to a longitudinal axis of the semiconductor device on a top surface of the second waveguide layer comprising a doped semiconductor material, and a longitudinal interdigitated transducer (IDT) formed on the top surface of the second waveguide layer or on the bottom surface of the first waveguide layer, the IDT extending longitudinally in a direction parallel to the longitudinal axis and being arranged to, in response to a signal from a signal generator, generate a surface acoustic wave (SAW) in a direction parallel to the longitudinal axis.

### BACKGROUND

This specification relates to tunable semiconductor laser devices comprising a surface acoustic wave (SAW) resonator. In particular, the specification relates to such a device comprising an interdigitated transducer (IDT), to a process for forming such a tunable semiconductor laser device and its operation.

A laser is a light emitting device that performs optical amplification to generate a narrow spectrum optical beam. Traditionally a diode laser is constructed using semiconductor materials. A p-n junction is formed by doping a crystal wafer to produce a p-type first region and an n-type second region. Applying a forward bias voltage to the p-n junction forces holes in the p-type region and electrons in the n-type region toward the p-n junction. The electrons and holes recombine in the p-n junction causing photons to emit from the region. The wavelength of the emitting photons is based on the transition energy which is the energy difference between an electron-hole pair and a recombined electron and hole. Subsequently these photons can stimulate further recombination in the p-n junction and thereby cause amplification.

A common design for the p-n junction structure is the double hetrostructure. In general, a hetrostructure is the contact layer between a low and a high bandgap material. A double hetrostructure consists of a layer of low bandgap material sandwiched between two layers of high bandgap material. The hetrostructure design is used to improve the efficiency of the laser. The low bandgap middle layer, known as the active layer, is the region where electron-hole pairs recombine and emit light. This middle layer is made thin so that it acts as a quantum well, confining the electron hole pairs, which further improves the efficiency of the laser.

To confine the light in the p-n junction, the hetrostructure itself is sandwiched between two layers of a lower index of refraction than the hetrostructure. These layers form a cladding that causes confinement of the light within the hetrostructure. This construction causes the active layer to act as a waveguide from which the light cannot escape, except at the end facets, where the light is meant, by design, to leave the device.

Every laser requires an optical feedback mechanism to ensure that the light does not immediately leave the active layer through the end facets, but instead is fed back instead into the active layer to causes more stimulated emission transitions. In general, optical feedback is required to make the device produce a laser beam. The region where optical gain exists, the active layer, forms in operation an optical amplifier. The feedback mechanism selects which wavelengths are fed back into the active layer for amplification and determines the central wavelength and the laser line width of the laser. Known lasers utilize a variety of means for creating optical feedback.

For example a Fabry-Perot laser provides reflective surfaces on the opposite ends of the active layer. Alternative means of creating an optical feedback mechanism is to engrave, for example by etching, a permanent periodical structure in the cladding near the active layer. The periodicity of the structure is chosen to selectively provide feedback for light with a particular laser wavelength by means of Bragg reflection. This type of laser diode is called a distributed feedback diode laser (DFB diode laser). In this type of laser, the optical field of the active layer can be said to be coupled to the periodical structure. In DFB diode lasers (here understood as: lasers where essentially the whole laser resonator comprises a periodic structure, in which Bragg reflection occurs), two types of coupling of the optical field of the active layer to the periodical structure are distinguished: index coupling and gain coupling. If the gain of the active layer is, by some means, periodically modified, the system is considered gain coupled. If the index of refraction of the cladding or of the active layer is periodically structured, the system is considered index coupled. The behavior of the laser is significantly different between gain and index coupled DFB diode lasers.

Another aspect in DFB diode lasers is the strength of coupling of the optical field of the active layer to the periodical modification. Generally, coupling can be characterized by one of the following three cases: over-coupled, under-coupled and critically-coupled. In the case of over coupling, the periodical modification is too strong which causes the laser not to function properly because the propagating light cannot exist in the active layer. In the under coupled case, the periodical structure is too weak to provide sufficient feedback and again which causes the laser to not function properly as well because the light exits the facets prematurely. Finally, in the critically coupled case the coupling is optimal for good laser characteristics. The exact strength of the coupling required to achieve critical coupling depends mainly on the gain. Usually, a narrow range of coupling strengths exists where critical coupling is present.

A tunable laser is a laser which has a wavelength that can be altered or specified based on a control input. Since a tunable laser does not have a single fixed central wavelength, a tunable laser requires an adjustable feedback system. For example, in order to implement a tunable laser using distributed feedback, means for introducing adjustable periodical deformation on the surface of material are utilized.

A surface acoustic wave (SAW) is an elastic deformation wave that propagates along the interface of a solid state material and vacuum or air or along the interface of two solid state materials with different velocities of sound. Well known examples of this type of wave are the Raleigh wave and the leaky surface acoustic wave. A pure SAW propagates only along the interface and it does not propagate away from that interface. Instead, perpendicularly away from the interface, the acoustical amplitude decays exponentially with increasing distance to the interface. The decay length is approximately equal to the wavelength of the SAW. Since the energy of the acoustical wave exists essentially only at the interface and in a thin region surrounding the interface, far less power is required to reach a certain level of acoustical pressure with SAW's than with bulk acoustical waves. Therefore, in order to achieve a certain level of acoustical pressure, SAW devices typically require only a fraction of the power of bulk acoustic wave devices. In general, when acoustical waves are generated, an increase in frequency leads to an increase in required power to excite the acoustical wave. Therefore, when generating SAW's instead of bulk acoustic waves, the reduction in required power levels is even greater when high frequency waves are generated. Furthermore, from an engineering perspective, SAW's are better controllable because they exist essentially only at the interface and are thus less likely to interfere with the rest of the device.

SAW's are generated by transforming an input signal into a periodical elastic deformation on the surface of a solid state material. The device that takes the input signal and transforms it into a SAW is called a SAW transducer. Typically, a SAW transducer consists of a layer of piezoelectric material on which is placed a set of periodically spaced line-like structures that are interconnected in an alternating manner. This type of SAW transducer is called an interdigitated transducer or IDT. A SAW is produced when an IDT is connected to an alternating current (AC) signal. In some designs, the spatial frequency of the generated SAW can only be equal to the spatial frequency of the line structures or a higher overtone thereof. This type of IDT is called a narrow band IDT. Alternatively, a broadband IDT utilizes a different design of line-like structures on the IDT to generate SAWs within a broad band of spatial frequencies. In general, the amplitude of the SAW as a function of the amplitude of the input signal is a monotonically rising function. The combination of the SAW transducer and a signal generator is here called the SAW generator.

Generally, to form a semiconductor structure, layers of materials are deposited sequentially on a substrate. Depending on the structure, each layer could require etching. Etching is the act of removing the uppermost layer of a material in the areas that are not protected by photoresist deposited during the etching process. A variety of etching processes are well known in the art. For example, dry etching, which utilizes plasma to remove the unprotected areas, is a commonly used process. Alternatively, wet etching which utilizes liquid chemical to dissolve unprotected areas can be used. Every etching process uses a masking material such as photoresist to mask or protect particular areas from the etching process. For example, the photoresist mask is patterned using photolithography to protect the portions of a layer to be etched that are part of the, structure. Each layer that requires etching must be etched separately.

In particular, the process of forming a tunable laser comprising an IDT could be a difficult multi-level process that requires many adjustments and calibrations. The present invention discloses efficient processes for forming a tunable laser with an integrated IDT that reduce the complexity of forming the device as well as minimize the size of the device.

### SUMMARY

This specification describes technologies relating to providing an improved tunable laser device and a method for fabricating such a device.

In general, one innovative aspect of the subject matter described in this specification can be embodied in methods that include the actions of forming a first doped cladding layer on a semiconductor substrate, the first doped cladding layer having a top surface and a bottom surface, the bottom surface in contact with the semiconductor substrate; forming a first waveguide layer of essentially undoped piezoelectric material on the top surface of the first doped cladding layer, the first waveguide layer having a top surface and a bottom surface, the bottom surface in contact with the top surface of the first doped cladding layer; forming an active layer on the top surface of the first waveguide layer, the active layer having atop surface and a bottom surface, the bottom surface in contact with the top surface of the first waveguide layer; forming a second waveguide layer of essentially undoped piezoelectric material on the top surface of the active layer, the second waveguide layer having a top surface and a bottom surface, the bottom surface in contact with the top surface of the active layer; forming a second doped cladding layer on the top surface of the second waveguide layer, the second doped cladding layer having a top surface and a bottom surface, the bottom surface in contact with the top surface of the second waveguide layer; etching a first portion of the second doped cladding layer from the top surface of the second doped cladding layer to form a longitudinal structure from a second portion of the second doped cladding layer, the longitudinal structure being in a direction parallel to a longitudinal axis of the semiconductor device; and forming a first longitudinal interdigitated comb structure on one of the top surface of the second waveguide layer or the bottom surface of the first waveguide layer, the interdigitated comb structure and the essentially undoped piezoelectric material being an interdigitated transducer (IDT) extending longitudinally in a direction parallel to the longitudinal axis and being arranged to, in response to a signal from a signal generator, generate a surface acoustic wave (SAW) in a direction parallel to the longitudinal axis.

Another innovative aspect of the subject matter described in this specification can be embodied in methods that include the actions of forming a first doped cladding layer on a semiconductor substrate, the first doped cladding layer having a top surface and a bottom surface, the bottom surface in contact with the semiconductor substrate; forming a first waveguide layer of essentially undoped piezoelectric material on the top surface of the first doped cladding layer, the first waveguide layer having a top surface and a bottom surface, the bottom surface in contact with the top surface of the first doped cladding layer; forming an active layer on the top surface of the first waveguide layer, the active layer having a top surface and a bottom surface, the bottom surface in contact with the top surface of the first waveguide layer; forming a second waveguide layer of essentially undoped piezoelectric material on the top surface of the active layer, the second waveguide layer having a top surface and a bottom surface, the bottom surface in contact with the top surface of the active layer; forming a second doped cladding layer on the top surface of the second waveguide layer, the second doped cladding layer having a top surface and a bottom surface, the bottom surface in contact with the top surface of the second waveguide layer; etching a first portion of the second doped cladding layer from the top surface of the second doped cladding layer to form a longitudinal structure and a longitudinal interdigitated transducer (IDT) from a second portion of the second doped cladding layer, the longitudinal structure being in a direction parallel to a longitudinal axis of the semiconductor device, the etching exposing a first surface portion of the second waveguide layer, and the IDT formed on the first surface portion of the second waveguide layer and extending longitudinally in a direction parallel to the longitudinal axis and being arranged to, in response to a signal from a signal generator, generate a surface acoustic wave (SAW) in a direction parallel to the longitudinal axis.

Another innovative aspect of the subject matter described in this specification can be embodied in a tunable semiconductor device that includes a first doped cladding layer on a semiconductor substrate, the first doped cladding layer having a top surface and a bottom surface, the bottom surface in contact with the semiconductor substrate; a first waveguide layer of essentially undoped piezoelectric material on the top surface of the first doped cladding layer, the first waveguide layer having a top surface and a bottom surface, the bottom surface in contact with the top surface of the first doped cladding layer; an active layer on the top surface of the first waveguide layer, the active layer having a top surface and a bottom surface, the bottom surface in contact with the top surface of the first waveguide layer; a second waveguide layer of essentially undoped piezoelectric material on the top surface of the active layer, the second waveguide layer having a top surface and a bottom surface, the bottom surface in contact with the top surface of the active layer; a longitudinal structure parallel to a longitudinal axis of the semiconductor device on the top surface of the second waveguide layer comprising a doped semiconductor material; and a longitudinal interdigitated transducer (IDT) formed on one of the top surface of the second waveguide layer or on the bottom surface of the first waveguide layer, the IDT extending longitudinally in a direction parallel to the longitudinal axis and being arranged to, in response to a signal from a signal generator, generate a surface acoustic wave (SAW) in a direction parallel to the longitudinal axis.

The details of one or more embodiments of the subject matter described in this specification are set forth in the accompanying drawings and the description below. Other features, aspects, and advantages of the subject matter will become apparent from the description, the drawings, and the claims.

### BRIEF DESCRIPTION OF THE DRAWINGS

FIG. 1A is cross-sectional view of an example embodiment of a tunable laser device comprising an integrated IDT.

FIG. 1B is an overhead view of an example embodiment of a tunable laser comprising an integrated IDT.

FIG. 2 is a flow diagram of an example process for forming a tunable laser comprising an integrated IDT.

FIG. 3A is cross-sectional view of an alternative example embodiment of a tunable laser comprising an integrated IDT.

FIG. 3B is flow diagram of an example process for forming an alternative example embodiment of a tunable laser comprising an integrated IDT.

FIG. 4 is cross-sectional view of a deep etching example embodiment of a tunable laser comprising an integrated IDT.

FIG. 5 is a flow diagram of a deep etching example process for forming a tunable laser comprising an integrated IDT.

Like reference numbers and designations in the various drawings indicate like elements.

### DETAILED DESCRIPTION

This invention provides a design where an IDT is placed laterally adjacent to an active region of a semiconductor laser device and adjacent to the path of the laser beam within. This arrangement allows the advantageous placement of the IDT adjacent to essentially the whole or the majority of the active region. Additionally, this arrangement advantageously prevents the problem of loss-coupling through the periodicity of the IDT structure. The IDT is designed such that an acoustic resonator will be formed in a region proximate to the active layer of the laser. A standing acoustic wave is formed, upon excitation, in that region and thereby a Doppler shift in the laser wavelength does not occur.

The end surfaces of the laser device may be end facets, but other boundaries of the semiconductor structure are also possible. The end surfaces must be designed such that they do not disturb the feedback by, for example, introducing strong Fabry Perot modes. This can be achieved by depositing antireflection coatings, slightly diagonal ridge waveguides (e.g. 1-10 degrees) or by curving at least a portion of the ridge waveguide in order to reduce reflections from an end surface or by simply avoiding end surfaces by placement (“butt coupling”) of a light absorber on one side and for example an optical fiber or arrayed waveguide grating on the other side. Further, a facet could be cleaved diagonally into the transversal direction in order to prevent SAWs from reflecting back along the surface but rather cause them to be scattered into the bulk of the material where they quickly are dissipated.

Power is coupled into the laser by injecting current that passes through the active region of the laser. The current may be drained using multiple methods such as, for example, a contact surface provided on the bottom surface. Alternatively, lateral power connections can be used to enable current injection from side to side.

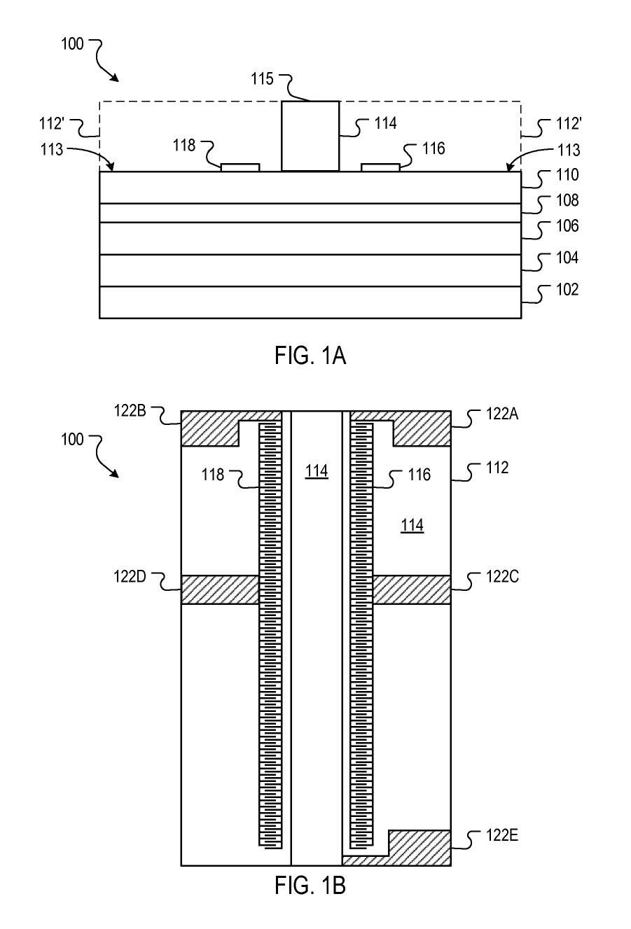

FIG. 1A and FIG. 1B respectively show a cross sectional view and an overhead view of an embodiment of a tunable laser device 100 comprising an integrated IDT. The relative dimensions in the figures are for illustrative purposes only, and, as depicted, are not to scale. The tunable laser is a semiconductor laser device comprising a p-n junction such as, for example, a III-V junction. In some embodiments a laser design could be a quantum cascade lasers, a separate confinement heterostructure, a quantum well laser, or a double heterostructure laser. A variety of materials could be used for forming the laser structure such as, for example, gallium arsenide (GaAs), indium, phosphate (InP), gallium antimonide (GaSb), and gallium nitride (GaN) or mixtures of these materials, such as InxGal-xAlyAsl-y. However, other suitable materials according the invention to form the laser structure can be used.

The laser device 100 as shown in FIGS. 1A and 1B comprises an active layer 108 sandwiched between a first waveguide layer 106 and a second waveguide layer 110. The waveguide layers are designed to confine the light in the active layer between the two waveguides. Accordingly, the light will propagate in the active layer. The laser device 100 is formed by depositing a first doped cladding layer 104 on top a substrate 102. A first waveguide layer 106 of essentially undoped piezoelectric material is then deposited on the top surface of the first cladding layer 104. An active layer 108 is formed on top of the first waveguide layer 106. The active layer 108 is a non-conducting layer with a low work function, designed to confine electron hole pairs injected into the laser device. A second waveguide layer 110 of essentially undoped piezoelectric material can be deposited on top of the active layer 108.

Atop the second waveguide layer 110 a second doped cladding layer 112′ is deposited. The second doped cladding layer 112′ is doped according to a first doping gradient having an increase in doping concentration in proportion to a vertical height of the longitudinal structure 114 as measured from a top surface 113 of the second waveguide layer 110. This doping gradient results in the bottom portion of the longitudinal structure that meets the top surface 113 being comprised of essentially undoped semiconductor material. Conversely, the top portion 115 of the longitudinal structure 114 is highly doped, relative to the essentially undoped portion of the longitudinal structure 114. In some implementations, the first doped cladding layer 104 may also have a similar doping gradient in the opposite direction such that top surface of the first doped cladding layer 104, which is in contact with the bottom surface of the first waveguide layer 106, is comprised of essentially undoped semiconductor material, and the bottom surface of the first doped cladding layer 104, which is in contact with the top surface of the substrate 102, is highly doped relative to the essentially undoped portion of the cladding layer 104.

The longitudinal structure 114 is shown as having a perpendicular edge from the top portion 115 to the top surface 113. However, in some implementations, the longitudinal structure 114 may comprise angled sides such that the top surface portion 115 is of smaller width than the base of the longitudinal structure 114. In still other implementations, the longitudinal structure 114 may comprise two or more layered stepped portions such that top portion 115, comprising a top stepped portion, is of smaller width than a bottom stepped portion that forms a base of the longitudinal structure 114.

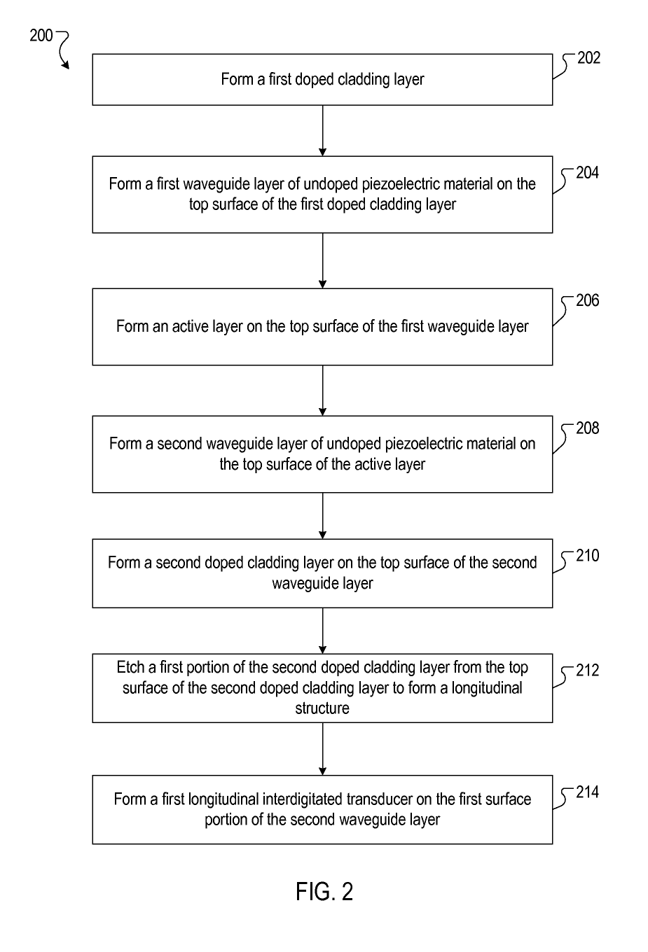

Several processes may then be used for forming embodiments of the current invention that include a longitudinal structure 114, a first longitudinal interdigitated comb structure 116, and a second longitudinal interdigitated comb structure 118 on top of the second waveguide layer. One example process for a first embodiment, as show in FIG. 1B, is described with respect to FIG. 2.

The first embodiment of the laser device 100 comprises a longitudinal structure 114 that forms a ridge waveguide (RWG). The ridge waveguide provides additional lateral confinement of the optical field, which results in fewer optical modes and a narrower laser line width. The first embodiment of the laser device 100 also comprises a conductive strip placed on top of the longitudinal structure 114 order to facilitate current injection.

The first embodiment of the laser device 100 also comprises one or more integrated IDTs. The embodiment as shown in FIG. 1A and FIG. 1B comprises two IDTs, wherein the first IDT comprises a comb structure 116 and the essentially undoped piezoelectric material beneath the comb structure 116, and the second IDT comprises a second comb structure 118 and the essentially undoped piezoelectric material. Both IDTs are placed on a shared single layer of the essentially undoped piezoelectric material of the second waveguide layer 110.

Each IDT extends in a longitudinal direction and comprises two interlocking combs as shown in FIG. 1B. The conducting material forming the comb structures 116 and 118 may be metal, such as gold. Alternatively, the IDT may be a structure comprising a richly doped semiconductor material. In general, the combs define interleaved areas of high and low electrical conductivity. For example, in the embodiment wherein the IDT's comb is formed by a conducting metal material, the teeth of the comb are the high conducting areas, and the gaps in between are the low conducting areas.

The essentially undoped piezoelectric material of the second waveguide layer 110 may be, for example, Quartz, Lithium Niobate, and Zinc Oxide or other essentially undoped semiconductors like InP, GaSb or GaAs. Because the laser device as shown in FIG. 1A comprises an exposed portion of the second waveguide which is a layer of essentially undoped piezoelectric semiconductor material, the comb structures can be placed directly on the exposed portion of the second waveguide. This eliminates the need to deposit an additional layer of piezoelectric material for the comb structures to be place on top of, in order to form one or more IDTs. As will be described with respect to FIG. 2 below, the cladding layer 112′, after being deposited on the second waveguide layer 110, is etched to form the longitudinal structure 114. Thus, the phantom areas of 112's are the portions of the cladding layer 112′ that have been removed by the etching process.

The laser device further comprises contact surfaces for each IDT. Contact pads 122A and 122C are connected to the first IDT 116 and are configured to receive an AC signal in order to generate a SAW. Similarly, Contact pads 122B and 122D are connected to the second IDT 118 and are configured to receive an AC signal in order to generate a SAW. For example, applying an electrical signal such as a Radio Frequency (RF) signal in the GHz range, a Surface Acoustic Wave (SAW) can be generated. Due to the longitudinal orientation of IDTs as shown in FIG. 1B, the SAWs will combine to form a single standing SAW in the longitudinal direction.

The IDTs are placed symmetrically on opposite sides of the longitudinal structure 114 as shown in FIG. 1A and FIG. 1B. For example, the symmetrical arrangement may specify a particular distance between the first IDT 116 and the parallel longitudinal structure 114 that is equal to the distance between the second IDT 118 and the parallel longitudinal structure. Such an arrangement generates a combined SAW that has an extremum amplitude between the first and second IDTs. However, the symmetrical design is not required according the inventions. In one embodiment of the invention the laser device may comprise a single IDT.

In operation, the longitudinal structure 114 is connected to a current via a contact pad 122E. By connecting a positive DC voltage to the top contact pad 122E and a ground DC voltage to a bottom contact surface, an electrical current may be injected into the laser. As the current flows through the laser device, the electron-hole pairs are forced to the active region where they recombine and produce photons. Accordingly, an optical beam is generated within the laser device. In particular, current is injected through the contact surface 122E and the longitudinal structure 114 into the bulk of the semiconductor material. The current is drained via a contact surface placed on the bottom of the substrate 102. The current causes the active region to be formed wherein the optical gain occurs in the active layer 108. The active region may typically be 1-10 micron wide and extends over essentially the entire length of the longitudinal structure 114. The interference of two running waves that are opposite in directions may produce a standing SAW, which is present over essentially the entire length of the IDTs generating the waves, and thus over essentially the entire length of the active region.

The SAW induces index of refraction variations in the laser material, which gives rise to a Bragg grating. The Bragg grating, having a periodicity that is depends on the frequency of the (RF) signal applied to the IDT and the velocity of the SAW. Accordingly, the Bragg grating can be controlled by the signal applied to the IDT. Thus, the controlled grating forms the optical feedback necessary for the laser to function. Changing the frequency of the IDT's input signal, in turn changes the laser's central wavelength. Accordingly, the central wavelength of the laser may be controlled.

The process 200 of FIG. 2 is an example process for forming the first embodiment of the tunable semiconductor laser device shown in FIG. 1A and FIG. 1B. First, a first doped cladding layer 104 is formed by depositing a layer of doped semiconductor material on top of the top surface of a substrate 102 (202). The substrate is a solid semiconductor material. The process 200 then forms a first waveguide layer 106 of essentially undoped piezoelectric material on top of the top surface of the first doped cladding layer 104 (204). The undoped piezoelectric material may be, for example a III/V semiconductor material. An active layer 108 is formed on top of the top surface of the first waveguide layer 106 (206). The active layer is non-conducting layer that has a low work function to ensure that the active layer confines electron-hole pairs. A second waveguide layer 110 of essentially undoped piezoelectric material is formed on the top surface of the active layer 108 (210), and then a second cladding layer 112′ is formed on top of the top surface of the second waveguide layer 110 (210). The second doped cladding layer 112′ is doped according the doping gradient described above.

The process 200 then etches a first portion of the second doped cladding layer 112′ from the top surface of the second doped cladding layer to form a longitudinal structure 114 (212). The etching removes the portions of the second doped cladding layer 112′, which are indicated by the phantom lines of FIG. 1A. This exposes a portion of the top surface 113 of the second waveguide layer 110. The remaining portion of the second cladding layer 112′ forms the longitudinal structure 114 acting as a ridge waveguide.

Finally, a first longitudinal interdigitated comb structure 116 is formed on the first surface portion 113 of the second wave guide layer 110 (214). The first comb structure 116 may be formed from a conductive metal, such as for example gold. The metal is arranged in an interleaved manner such as shown in FIG. 1B elements 116 (and 118, which is a second combed structure that is formed). The comb structure 116 can be formed, for example, by depositing a metal layer on top of first portion of the top surface 113 of the second waveguide layer 110, and etching the metal layer accordingly to form the described comb structure 116. Forming the comb structure on top of the exposed area of the essentially undoped piezoelectric second wave guide layer forms the integrated IDT within the tunable semiconductor laser device.

The second waveguide 110 thus serves two functions. The first function is to confine the light beneath its lower surface. The second function is to provide an essentially piezoelectric material that is utilized in forming the integrated IDT structures. In the embodiment shown in FIG. 1A, the second waveguide is part of the first IDT comprising comb structure 116 and is also a part of the second IDT comprising comb structure 118. This reduces the complexity of forming the tunable laser comprising the integrated IDT as well as reduces the overall size of the device.

In an embodiment of the invention, the first and second comb structures are placed symmetrically with respect to the longitudinal structure 114 and extend in parallel to the longitudinal structure extending essentially over the entire length of the device. Such embodiment allows for the generation of a standing SAW having an extremism value at a location within or beneath the longitudinal structure 114 over the entire length of the device.

In an alternative embodiment, the second IDT may be shorter than first IDT. Additionally, the second IDT may have a different periodicity than the first IDT. Such an arrangement of two IDTs may, for example, provide coverage of a broader range of optical wavelengths, and subsequently increase the tuning range of the laser.

In an embodiment, the distance or void in the lateral direction between the longitudinal structure and the one or more comb structures is between 50 nm and 100 micron (μm), preferably between 100 nm-10 micron. In an embodiment, the distance between the center of the active region and the comb structure of the IDT is between 50 nm and 150 micron (μm), preferably between 100 nm-15 micron.

The optical wavelength may be described by the following formula:

λₒₚₜᵢₒₙₐₗ=2nv_{accoustic}/(of)

wherein n is the refractive index of the material, o is the Bragg grating order, v_{accoustic} SAW velocity and the RF frequency of the SAW.

The surface acoustic wave partially penetrates into the semiconductor material towards the active layer and generates regular refractive index variations in the diode material. Mathematically, an index of refraction can be represented as a complex number n+ik, where k>0 signifies loss (dampening) and k<0 means gain. The regular index variations give rise to regular reflections, thus forming an acoustically induced Bragg grating. A lower grating order requires a higher RF frequency, whereas a higher order has more advantageous minimum feature sizes. For lasers, SAWs having a frequency in the GHz range are used in order to set up a suitable Bragg grating. In some embodiments, the device is adapted for forming, under operating conditions, a Bragg grating having an uneven order with respect to the desired laser wavelength, preferably a low uneven order, such as first order, third order, or fifth order. In some embodiments, the order is preferably smaller than 10.

The ranges above may give adequate SAW induced gratings while preventing loss coupling. In particular, the SAW is generated by the teeth of a comb structure, and thus as the distance from the tips of the teeth of the comb structure increases, the strength of the SAW decreases. Therefore, the tips of the teeth must not be too far away from the RWG, otherwise there is not enough coupling of the SAW with the optical field. For example, assume the device 100 is a quantum cascade laser at a wavelength of 10 μm and operates at a SAW grating of 9th order. Accordingly, the acoustical wavelength is around 20 μm. Since the amplitude of the acoustical wave decays exponentially in any non-propagating direction, the amplitude will decrease as exp(−d/lambda). As an estimate of reasonable threshold would be, for example, exp(−5) of the amplitude of the SAW inside the transducer. Thus, a maximum workable distance of 5×20 μm is obtained.

On the other hand, as the distance from the tips of teeth of the comb structure to the RWG decreases below a particular threshold, such as for example 100 nm, a significant overlap of the optical field with the teeth will occur. In such case a loss coupled DFB is formed, and which cannot be tuned. In other words, the distance between the tips of the teeth of comb structure must be above a first threshold, such that a minimal or overlap occurs between optical field and tips of the teeth. The distance must also be below a second threshold, such that the coupling between the SAW and the optical field is strong enough to affect the optical field according to the invention as described above.

Thus the comb structure must not dominate the effect of the SAW through influence on the optical field emerging from the active region of the device. If, for example, the comb structure were to be in contact with the RWG, then the optical field would be essentially completely absorbed by the comb structure due to ohmic losses. Conversely, when the influence of the comb structures is less than the influence of the index variations caused by the SAW (e.g., about 10%) the SAW will dominate the optical feedback and a tunable laser can be made. This condition arises at about 50 nm distance and above; however, the specific distance will depend on the design and dimensions of the laser diode.

In an embodiment according the invention, the interleaved conducting lines may be 20-200 nm, preferably 50-100 nm high and 10-250 micron, preferably 20-100 micron long in the lateral direction. In an embodiment according the invention, the longitudinal structure 114, has a height extending in a direction protruding from the top surface of at least 0.05 micron, preferably at least 1.0 micron, and at most 5.0 micron. Finally, the longitudinal dimension may be 5%-50%, preferably 20%-30% of the SAW's wavelength.

The laser device may be combined with one or more integrated signal generators, in particular an RF signal generators, so that each IDT of the laser device is connected to an integrated signal generator. In such an embodiment, the contact pads 122A, 122B, 122C, and 122D can be made smaller or eliminated altogether and replaced by conducting lines to the respective contact surfaces or connection points of the integrated signal generators. The skilled person will be aware of suitable signal generator designs that can be advantageously integrated with a tunable semiconductor laser according the invention, even integrated on the same chip as the semiconductor laser. A tunable laser with an integrated signal generator may be formed from essentially the same semiconductor material. In an embodiment integrating these functionalities within one chip, the need to generate RF outside laser device can be eliminated.

In some embodiments a layer of insulating materials and a layer of polymer may be deposited on top of the etched surface 112′. Additionally, a layer of conducting metallic contact may be deposited on the top of the longitudinal structure 114. In some embodiments, the insulating material may be Al₂O₃ and the metallic contact may be a gold metallic contact.

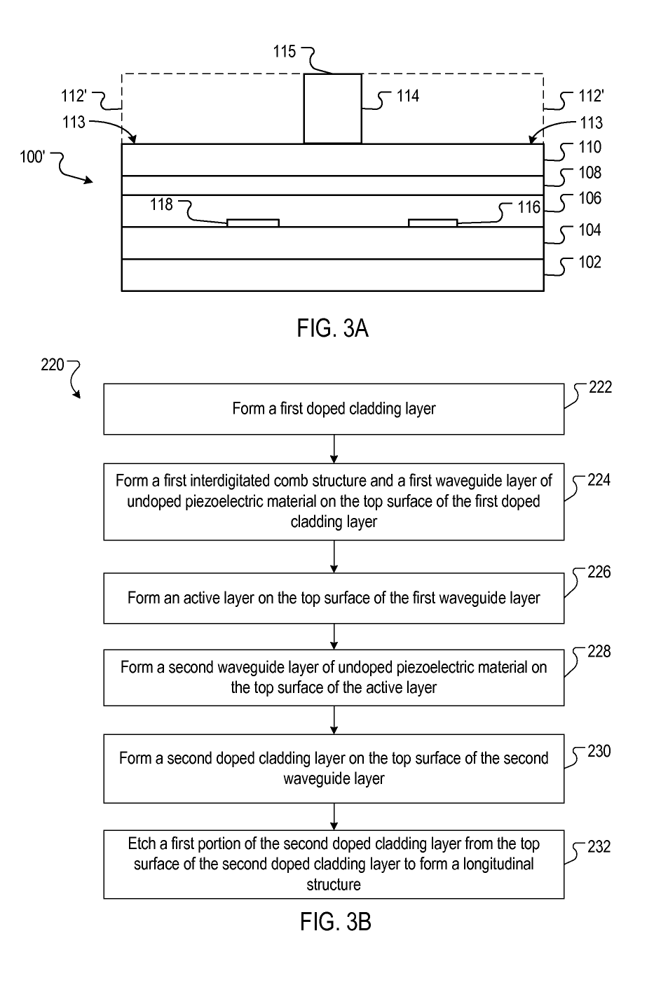

FIG. 3A shows an alternative embodiment of a tunable laser device comprising an integrated IDT. A process 220 that is similar to the process 200 for forming the alternative embodiment is disclosed in the flow chart of FIG. 3B. In this embodiment, the comb structures 116 and 118 are included in the first essentially undoped waveguide layer 106.

Process 220 begins by forming a first doped cladding layer 104 on top of the top surface of the substrate 102 (222). Thereafter, a first interdigitated comb structure 116 is formed on top of the top surface of the first doped cladding layer 104, and a first wave guide layer 106 of an essentially undoped semiconductor material is formed on top of the comb structure and the first doped cladding layer 104 (224). The rest of the process 220 is similar to process 200. The remaining layers are sequentially deposited on top of one another, and the second doped cladding layer 112′ is etched to form the longitudinal structure 114. In this embodiment, however there is no IDT placed on top of the second waveguide layer.

In other embodiments, additional IDTs may be formed on top of the second wave guide layer as well as beneath the first waveguide layer. Different arrangements wherein the interdigitated comb structure is placed in contact with the first wave guide layer, the second wave guide layer, or other essentially piezoelectric materials within the laser device can also be used.

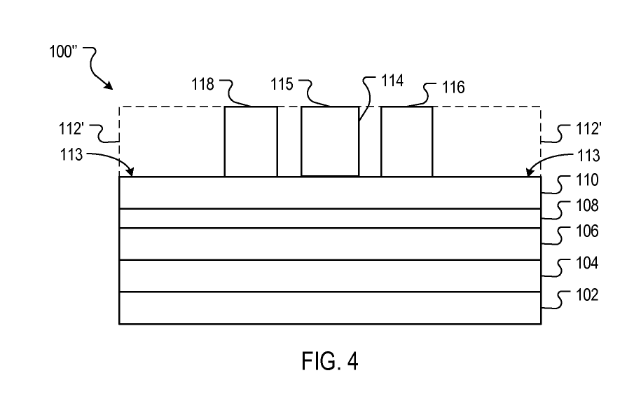

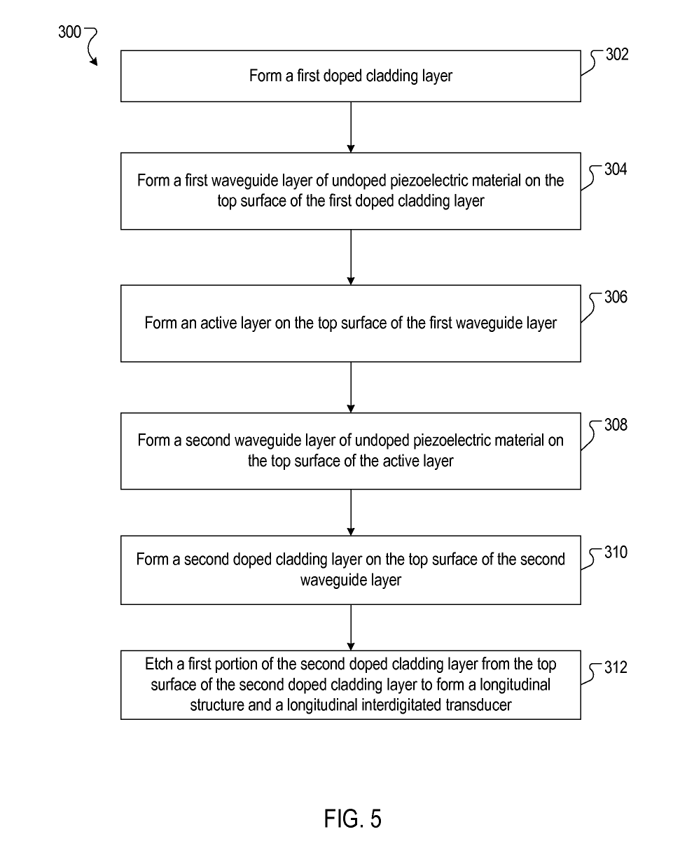

FIG. 4 shows yet another embodiment of the invention. In this embodiment, the comb structures 116 and 118 are formed from the upper cladding layer, with the longitudinal structure 114, during an etching process. An example process for fabricating the device 100″ is described with respect to FIG. 4, which is a flow diagram of a deep etching example process 300 for forming the device 110″.

Because the longitudinal structure 114 and the comb structures 116 and 118 are formed from the doped semiconductor material of the cladding layer 112, both the longitudinal structure 114 and the comb structures 116 and 118 have the same doping gradient in which there is an increase in doping concentration in proportion to a vertical height of the longitudinal structure 114 as measured from the top surface 113 of the second waveguide layer 110. The comb structures 116 and 118 of are a height equal to the longitudinal structure 114.

Steps 302, 304, 306, 308, 310 and 312 of the process 300 are similar to steps 202, 204, 206, 208, 210 and 212 of the process 200. However, step 314 of the process 300 etches a first portion of the second doped cladding 112′ layer from the top surface of the second doped cladding layer 112 to form the longitudinal structure 114 and the longitudinal comb structure 116. Thus the comb structures 116 and 118, as well as the longitudinal structure 114 are formed from the second doped cladding layer.

Accordingly, in deep etching embodiments the height of the comb structure may be equal to the height of the longitudinal structure 114 as shown in FIG. 4. Additionally, since the comb structures and the longitudinal structure are formed from a single layer of a particular material comprising a particular doping gradient, the doping gradient may be identical in both structures. This embodiment further reduces the complexity of forming the tunable laser device by forming an entire IDT from layers already existing in a laser device.

In operation, the device may require a reverse DC bias in addition to the RF signal in order to ensure that the RF signal is not shorted through the substrate below and increases the Schottky barrier. This facilitates better power coupling to the SAW. Additional variations and embodiments similar to the variations and embodiments discussed above may also be implemented in the deep etched tunable laser device.

While this specification contains many specific implementation details, these should not be construed as limitations on the scope of any inventions or of what may be claimed, but rather as descriptions of features specific to particular embodiments of particular inventions. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described above should not be understood as requiring such separation in all embodiments, and it should be understood that the described components and systems can generally be integrated together in a single product.

Thus, particular embodiments of the subject matter have been described. Other embodiments are within the scope of the following claims. In some cases, the actions recited in the claims can be performed in a different order and still achieve desirable results. In addition, the processes depicted in the accompanying figures do not necessarily require the particular order shown, or sequential order, to achieve desirable results.

What is claimed is:

1. A process for forming a semiconductor device, comprising:
forming a first doped cladding layer on a semiconductor substrate, the first doped cladding layer having a top surface and a bottom surface, the bottom surface in contact with the semiconductor substrate;
forming a first waveguide layer of essentially undoped piezoelectric material on the top surface of the first doped cladding layer, the first waveguide layer having a top surface and a bottom surface, the bottom surface in contact with the top surface of the first doped cladding layer;
forming an active layer on the top surface of the first waveguide layer, the active layer having a top surface and a bottom surface, the bottom surface in contact with the top surface of the first waveguide layer;
forming a second waveguide layer of essentially undoped piezoelectric material on the top surface of the active layer, the second waveguide layer having a top surface and a bottom surface, the bottom surface in contact with the top surface of the active layer;
forming a second doped cladding layer on the top surface of the second waveguide layer, the second doped cladding layer having a top surface and a bottom surface, the bottom surface in contact with the top surface of the second waveguide layer;
etching a first portion of the second doped cladding layer from the top surface of the second doped cladding layer to form a longitudinal structure from a second portion of the second doped cladding layer, the longitudinal structure being in a direction parallel to a longitudinal axis of the semiconductor device; and
forming a first longitudinal interdigitated comb structure on one of the top surface of the second waveguide layer or the bottom surface of the first waveguide layer, the interdigitated comb structure and the essentially undoped piezoelectric material being a interdigitated transducer (IDT) extending longitudinally in a direction parallel to the longitudinal axis and being arranged to, in response to a signal from a signal generator, generate a surface acoustic wave (SAW) in a direction parallel to the longitudinal axis.

2. The process of claim 1, wherein:
forming a first longitudinal interdigitated comb structure on one of the top surface of the second waveguide layer or the bottom surface of the first wave guide layer comprises:
forming the first longitudinal interdigitated comb structure on a top surface portion of the second waveguide layer by depositing a metal layer on the top surface portion of the second waveguide.

3. The process of claim 2, forming the first longitudinal interdigitated comb structure on the top surface portion of the second waveguide layer comprises forming the first longitudinal interdigitated comb structure extending essentially over an entire length of the active layer and spaced apart from the longitudinal structure.

4. The process of claim 3, wherein forming the first longitudinal interdigitated comb structure on the top surface portion of the second waveguide layer comprises forming the first longitudinal comb structure spaced apart from the longitudinal structure by a distance between 50 nm and 100 micron (μm).

5. A process for forming a semiconductor device, comprising:
forming a first doped cladding layer on a semiconductor substrate, the first doped cladding layer having a top surface and a bottom surface, the bottom surface in contact with the semiconductor substrate;
forming a first waveguide layer of essentially undoped piezoelectric material on the top surface of the first doped cladding layer, the first waveguide layer having a top surface and a bottom surface, the bottom surface in contact with the top surface of the first doped cladding layer;
forming an active layer on the top surface of the first waveguide layer, the active layer having a top surface and a bottom surface, the bottom surface in contact with the top surface of the first waveguide layer;
forming a second waveguide layer of essentially undoped piezoelectric material on the top surface of the active layer, the second waveguide layer having a top surface and a bottom surface, the bottom surface in contact with the top surface of the active layer;
forming a second doped cladding layer on the top surface of the second waveguide layer, the second doped cladding layer having a top surface and a bottom surface, the bottom surface in contact with the top surface of the second waveguide layer;
etching a first portion of the second doped cladding layer from the top surface of the second doped cladding layer to form a longitudinal structure and a longitudinal interdigitated transducer (IDT) from a second portion of the second doped cladding layer, the longitudinal structure being in a direction parallel to a longitudinal axis of the semiconductor device, the etching exposing a first surface portion of the second waveguide layer, and the IDT formed on the first surface portion of the second waveguide layer and extending longitudinally in a direction parallel to the longitudinal axis and being arranged to, in response to a signal from a signal generator, generate a surface acoustic wave (SAW) in a direction parallel to the longitudinal axis.

6. The process of any of claim 1 or 5, wherein forming the first waveguide layer and forming the second waveguide layer comprises forming the first waveguide layer and forming the second waveguide layer from a III/V semiconductor material.

7. The process of claim 5, wherein etching the first portion of the second doped cladding layer from the top surface of the second doped cladding layer to form the longitudinal structure and the longitudinal interdigitated transducer from the second portion of the second doped cladding layer comprises forming the first longitudinal interdigitated transducer extending essentially over an entire length of the active layer and spaced apart from the longitudinal structure.

8. The process of claim 7, wherein forming the first longitudinal interdigitated transducer extending essentially over an entire length of the active layer and spaced apart from the longitudinal structure comprises forming the first longitudinal interdigitated transducer spaced apart from the longitudinal structure by a distance between 50 nm and 100 micron (μm).

9. A tunable semiconductor device, comprising:
a first doped cladding layer on a semiconductor substrate, the first doped cladding layer having a top surface and a bottom surface, the bottom surface in contact with the semiconductor substrate;
a first waveguide layer of essentially undoped piezoelectric material on the top surface of the first doped cladding layer, the first waveguide layer having a top surface and a bottom surface, the bottom surface in contact with the top surface of the first doped cladding layer;
an active layer on the top surface of the first waveguide layer, the active layer having a top surface and a bottom surface, the bottom surface in contact with the top surface of the first waveguide layer;
a second waveguide layer of essentially undoped piezoelectric material on the top surface of the active layer, the second waveguide layer having a top surface and a bottom surface, the bottom surface in contact with the top surface of the active layer;
a longitudinal structure parallel to a longitudinal axis of the semiconductor device on the top surface of the second waveguide layer comprising a doped semiconductor material; and
a longitudinal interdigitated transducer (IDT) formed on the top surface of the second waveguide layer or on the bottom surface of the first waveguide layer, the IDT extending longitudinally in a direction parallel to the longitudinal axis and being arranged to, in response to a signal from a signal generator, generate a surface acoustic wave (SAW) in a direction parallel to the longitudinal axis.

10. The tunable semiconductor device of claim 9, wherein:
the doped semiconductor material of the longitudinal structure parallel to the longitudinal axis of the semiconductor device on the top surface of the second waveguide layer is doped according to a first doping gradient having an increase in doping concentration in proportion to a vertical height of the longitudinal structure as measured from the top surface of the second waveguide layer; and
the longitudinal interdigitated transducer is formed on the top surface of the second waveguide layer and is of a height equal to the longitudinal structure and comprises a doped semiconductor material that is doped according to the first doping gradient.

11. The tunable semiconductor device of claim 9, wherein the longitudinal interdigitated transducer is formed on the top surface of the second waveguide layer and comprises a longitudinal interdigitated comb structure on the top surface of the second waveguide layer.

12. The tunable semiconductor device of any of claim 10 or 11, wherein the first longitudinal interdigitated transducer extends essentially over an entire length of the active layer and is spaced apart from the longitudinal structure.

13. The tunable semiconductor device of claim 11, wherein the first longitudinal interdigitated transducer is spaced apart from the longitudinal structure by a distance between 50 nm and 100 micron (μm).

14. The tunable semiconductor device of claim 11, wherein the first longitudinal interdigitated transducer is configured to receive a reverse bias DC voltage during operation.
